(19) United States
(12) Patent Application Publication
(10) Pub. No.: US 2025/0104960 A1
(43) Pub. Date: Mar. 27, 2025

(54) OPERANDO SCANNING ELECTRON MICROSCOPY PLATFORM AND METHODS OF USING THE SAME

(71) Applicant: BOARD OF REGENTS, THE UNIVERSITY OF TEXAS SYSTEM, Austin, TX (US)

(72) Inventors: Wen Song, Austin, TX (US); Artur Davletshin, Austin, TX (US)

(21) Appl. No.: 18/895,633

(22) Filed: Sep. 25, 2024

Related U.S. Application Data
(60) Provisional application No. 63/584,951, filed on Sep. 25, 2023.

(51) Int. Cl. H01J 37/20; H01J 37/28

(52) U.S. Cl. CPC H01J 37/20; H01J 37/28

(57) ABSTRACT

Disclosed herein is an operando scanning electron microscopy platform comprising: a first cell comprising: (a) a sample well configured to receive a solid sample having at least one dimension up to about 20 mm; and (b) one or more electron beam transparent coverings positioned above the solid sample; wherein the platform is sealed and configured to withstand a pressure up to about 10 MPa and a temperature up to about 500° C. Also disclosed are methods of using the same.

### CROSS-REFERENCE TO RELATED APPLICATION

This application claims the benefit of U.S. Provisional Application 63/584,951, filed Sep. 25, 2023, the contents of which are hereby incorporated in its entirety.

### STATEMENT OF GOVERNMENT SUPPORT

This invention was made with government support under Grant no. CBET2145374 awarded by the National Science Foundation. The government has certain rights in the invention.

### BACKGROUND

Operando visualization techniques can allow the characterization and understanding of fluid behavior at the micro/nanoscales. For example, geochemical microfluidics optical microscopy platforms fabricated or functionalized with geologic minerals that mimic the pore geometry and surface mineralogy of natural geologic materials enable the optical microscopy of complex multiphase, microscale reactive transport processes in situ. While useful to understand some of the phenomena, this approach hinges on the use of optical wavelengths where spatial resolutions are limited to ˜100 nm to μm. Nanoscopic (i.e., <100 nm) dynamic fluid resolution is enabled by recent developments in liquid-phase transmission electron microscopy (TEM), where fluid samples are isolated from the TEM vacuum chamber using a parallel pair of electron-transparent membranes. However, these approaches still lack the ability to visualize and measure in situ nanoscale fluid-solid interactions confined in porous materials such as argillaceous rock.

Thus, there is a need for high spatial resolution electron-microscopy methods of operando visualization. Also, there is a need for a platform that would allow such a visualization. These needs and other needs are at least partially satisfied by the present disclosure.

### SUMMARY

The present invention is directed to an operando scanning electron microscopy platform comprising: a first cell comprising: (a) a sample well configured to receive a solid sample having at least one dimension up to about 20 mm; and (b) one or more electron beam transparent coverings positioned above the solid sample; wherein the platform is sealed and configured to withstand a pressure up to about 10 MPa and a temperature up to about 500° C.

In some aspects, the operando scanning electron microscopy platform disclosed herein further comprises a second cell having dimensions effective to encompass the first cell, wherein the second cell is at least partially thermally insulating the first cell.

In yet still further aspects, also disclosed herein is a method comprising positioning any of the disclosed herein examples of operando scanning electron microscopy platform, wherein the platform comprises a solid sample having at least one dimension up to about 20 mm, in an electron microscope chamber; optionally heating and/or pressuring the sample to a temperature up to about 500° C. and/or pressure of 10 MPa; and imaging the solid sample.

Also disclosed herein is an electron microscope comprising a chamber configured to receive the operando scanning electron microscopy platform of any one of the disclosed herein examples.

Additional aspects of the disclosure will be set forth, in part, in the detailed description, figures, and claims which follow, and in part will be derived from the detailed description, or can be learned by practice of the invention. It is to be understood that both the foregoing general description and the following detailed description are exemplary and explanatory only and are not restrictive of the invention as disclosed.

### BRIEF DESCRIPTION OF DRAWINGS

FIGS. 1A-1F depict an operando scanning electron microscopy (SEM) platform that enables direct in situ imaging of dynamic fluid-solid interactions in nanoporous materials according to some aspects disclosed herein. FIG. 1A shows an exemplary platform in one aspect. FIGS. 1B-1F show an exemplary thermal control up to 450° C. with (i) non-isothermal and (ii) isothermal modulation (FIG. 1B); operando spatial resolutions obtained down to ˜2.5 nm/pixel (FIG. 1C); temporal resolutions up to ˜10 fps (FIG. 1D); spatial elemental mapping using energy dispersive X-ray spectroscopy (EDS) (FIG. 1E), and liquids-gas-solids interfacial imaging at elevated temperatures and pressures (FIG. 1F).

FIG. 2 depicts an exemplary outer cell insulation cover.

FIGS. 3A-3E depicts in situ imaging of heat-induced fracturing in organic-rich argillaceous sediments using the disclosed herein operando platform. FIG. 3A shows (i) a heated shale sample comprised primarily of clay minerals (light gray material) with an initially intact piece of organic matter (dark gray material, OM); (ii, iii) a shale sample during non-isothermal heating (i.e., ΔT/Δt>0), where microfractures nucleate at curved organic/inorganic material interfaces and propagate into the mineral matrix. FIG. 3B shows in situ fracture aperture characterization, which shows that fracturing initiates at temperatures above ˜150° C. During non-isothermal heating, apertures open with increasing temperature and heating rate (e.g., ΔT/Δt=7.5 and 3° C./min). FIG. 3C illustrates that a correlation with thermogravimetric analyses shows that microfracture nucleation and propagation are controlled by the vaporization of light and heavy hydrocarbon components (regimes II and III, respectively, blue-shaded region). Here, hydrocarbon vapors trapped by the surrounding low permeability mineral matrix (˜nD) are unable to evacuate its source pore space and result in local pressure buildup, stress concentration, and stress failure at the tips of the lens-shaped OM. Vapors arising from moisture content are secondary here, with minimal fracturing observed at temperatures<150° C. (regime I, pink-shaded region). FIGS. 3D-3E show that multiphase transport characteristics of the fractured shale are controlled by the heating rate. High thermal stress (D, ΔT/Δt=7.5° C./min) results in gas-saturated fractures that allow water imbibition, whereas fractures generated during slow heating (E, ΔT/Δt=3° C./min) are saturated with hydrocarbon liquids that impede water transport.

FIGS. 4A-4E depict a pore development in organic-rich shale due to solid organic matter decomposition during high temperature heating. FIG. 4A shows a shale sample (i) with two organic matter fragments (OM 1, OM 2), which was heated at temperatures exceeding the pyrolysis threshold (T=373° C.>350° C.); (ii) thermal decomposition of solid kerogen is observed after 3 hours of isothermal heating at the organic-mineral interface. Here, new organic- and mineral-fluid interfaces are created. Interestingly, two kerogen fragments in close proximity to one another (OM 1 and OM 2) experience differential rates of thermal decomposition.

FIG. 4B shows a fluid-solid interface evolution of a single kerogen fragment where the mineral surface generated is relatively constant over time, showing that decomposition initiates at the mineral-organic interface. Decreasing organic surfaces with reaction corresponds with the decreasing volume of kerogen from the organic-mineral interface. FIG. 4C shows that a microscale compositional heterogeneity between adjacent kerogen fragments leads to differential rates of organic surface generation. FIG. 4C depicts a quantification of in situ measurements that show that thermal decomposition for individual kerogen fragments is best described using a first-order reaction model where the kinetics are described by the Arrhenius equation. FIG. 4D shows that differential rates of thermal decomposition between adjacent kerogen fragments are captured by distinct activation energies, Eₐ, and hence chemical composition.

FIGS. 5A-5E depict In situ nanoscale fluid-solid interactions. FIG. 5A shows a shale sample subjected to thermal stress, which was heated from 25 to 370° C. Organic matter decomposition is observed, including the generation of hydrocarbon liquids and gases in the newly created pore space. FIGS. 5B-5C depict the results of a contact angle characterization in situ that show the newly generated pore surfaces are oil-wetting. Oil wets both the (FIG. 5B) mineral and (FIG. 5C) organic surfaces in the presence of gas. FIG. 5D shows that pores generated from kerogen decomposition between the mineral and organic solids are imbibed spontaneously with hydrocarbon liquids. Oil-saturated flow paths impede the transport of radionuclide-contaminated aqueous phases. FIG. 5D shows that water is non-wetting in the pore spaces between organic and mineral solids in the presence of hydrocarbon liquids.

FIG. 6 depicts thermally-compatible platform assembly for operando visualization during heating. The visualization platform discussed in the main text is insulated thermally from the SEM chamber using ceramic thermal insulation that is held within an outer stainless-steel case. Ceramic material (Alumina Ceramic, McMaster-Carr) is placed between the visualization platform and the outer stainless steel case. The outer stainless-steel case (316SS) encloses the insulation, with ports for thermocouple and heater power cable connections to the Arduino control board.

FIG. 7 depicts calibration data for thermocouple measurements inside the sample well and on the compression cover measured in SEM vacuum.

FIG. 8 depicts an Arduino Control board circuit for enabling heat delivery and temperature measurements.

FIG. 9 depicts X-ray diffraction pattern of the shale sample. Major phases include quartz fragments (Q) and clay minerals kaolinite (K), illite (I), and smectite(S).

FIG. 10 depicts microfracture generation in the shale mineral matrix by local thermo-chemical-mechanical stress. Top-left and bottom left: initial and stressed states of the shale sample, showing the nucleation and growth of microfractures initiating from the curved ends of organic matter undergoing thermolysis. Top right and bottom right: Numerical model of stress concentration showing localization around the curved kerogen tip. Here, low permeability through the mineral matrix results in a local pressure buildup. Stress concentration at the curved tips of the organic matter fragments suggest that fractures propagate preferably from the tips of the organic matter, which is consistent with experimental observations.

FIG. 11 depicts operando SEM image series of organic matter fragments OM1 and OM2 in FIGS. 4B, C, and E during heating at elevated temperatures. Scale bar corresponds to the 50 μm. Parallel strips sloping from the top right to the bottom left are imaging artefacts of the SEM.

FIG. 12 depicts operando SEM image series of the organic matter fragment used to compile FIG. 4E (OM3) during heating at elevated temperatures. Scale bar corresponds to the 50 μm. Parallel strips sloping from the top right to the bottom left are imaging artefacts of the SEM.

FIG. 13 depicts operando SEM image series of the organic matter fragment used to compile FIG. 4D during heating at elevated temperatures. Scale bar corresponds to the 50 μm.

FIG. 14 depicts operando SEM image series of microfracturing during heating at rates of ˜3° C./min used in FIG. 2B. Scale bar corresponds to the 50 μm.

FIG. 15 depicts finite element simulations of the internal stress of shale samples confined in the stainless steel sample well as a result of differential thermal expansion during heating experiments. Thermal expansion coefficients used were 17.2×10⁻⁶° C.⁻¹ for stainless steel and 20×10⁻⁶° C.⁻¹ for shale.

### DETAILED DESCRIPTION

The present invention can be understood more readily by reference to the following detailed description, examples, drawings, and claims, and their previous and following description. However, before the present articles, systems, and/or methods are disclosed and described, it is to be understood that this invention is not limited to the specific or exemplary aspects of articles, systems, and/or methods disclosed unless otherwise specified, as such can, of course, vary. It is also to be understood that the terminology used herein is for the purpose of describing particular aspects only and is not intended to be limiting.

The following description of the invention is provided as an enabling teaching of the invention in its best, currently known aspect. To this end, those skilled in the relevant art will recognize and appreciate that many changes can be made to the various aspects of the invention described herein while still obtaining the beneficial results of the present invention. It will also be apparent that some of the desired benefits of the present invention can be obtained by selecting some of the features of the present invention without utilizing other features. Accordingly, those of ordinary skill in the pertinent art will recognize that many modifications and adaptations to the present invention are possible and may even be desirable in certain circumstances and are a part of the present invention. Thus, the following description is again provided as illustrative of the principles of the present invention and not in limitation thereof.

### Definitions

As used herein, the singular forms “a,” “an,” and “the” include plural referents unless the context clearly dictates otherwise. Thus, for example, reference to a “rare earth element” includes aspects having two or more such rare-earth elements unless the context clearly indicates otherwise.

Ranges can be expressed herein as from “about” one particular value and/or to “about” another particular value. When such a range is expressed, another aspect includes from the one particular value and/or to the other particular value. Similarly, when values are expressed as approximations, by use of the antecedent “about,” it will be understood that the particular value forms another aspect. It should be further understood that the endpoints of each of the ranges are significant both in relation to the other endpoint and independently of the other endpoint.

Similarly, when values are expressed as approximations, by use of the antecedent “about,” it will be understood that the particular value forms another aspect. It will be further understood that the endpoints of each of the ranges are significant both in relation to the other endpoint and independently of the other endpoint. Unless stated otherwise, the term “about” means within 5% (e.g., within 2% or 1%) of the particular value modified by the term “about.”

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, a description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6 and any whole and partial increments therebetween. This applies regardless of the breadth of the range.

As used herein, the terms “optional” or “optionally” mean that the subsequently described event or circumstance may or may not occur, and that the description includes instances where said event or circumstance occurs and instances where it does not.

References in the specification and concluding claims to parts by weight of a particular element or component in a composition or article, denotes the weight relationship between the element or component and any other elements or components in the composition or article for which a part by weight is expressed. Thus, in a composition or a selected portion of a composition containing 2 parts by weight of component X and 5 parts by weight component Y, X and Y are present at a weight ratio of 2:5, and are present in such ratio regardless of whether additional components are contained in the composition.

A weight percent of a component, unless specifically stated to the contrary, is based on the total weight of the formulation or composition in which the component is included.

Throughout the description and claims of this specification, the word “comprise” and other forms of the word, such as “comprising” and “comprises,” means including but not limited to, and are not intended to exclude, for example, other additives, segments, integers, or steps. Furthermore, it is to be understood that the terms comprise, comprising, and comprises as they relate to various aspects, elements, and features of the disclosed invention also include the more limited aspects of “consisting essentially of” and “consisting of.”

For the terms “for example” and “such as,” and grammatical equivalences thereof, the phrase “and without limitation” is understood to follow unless explicitly stated otherwise.

As used herein, the term “substantially,” when used in reference to a composition, refers to at least about 80%, at least about 85%, at least about 90%, at least about 91%, at least about 92%, at least about 93%, at least about 94%, at least about 95%, at least about 96%, at least about 97%, at least about 98%, at least about 99%, or about 100% by weight, based on the total weight of the composition, of a specified feature or component.

As used herein, the term “substantially,” in, for example, the context “substantially free,” refers to a composition having less than about 1% by weight, e.g., less than about 0.5% by weight, less than about 0.1% by weight, less than about 0.05% by weight, or less than about 0.01% by weight of the stated material, based on the total weight of the composition.

As used herein, the term “substantially,” in, for example, the context “substantially identical” or “substantially similar,” refers to a method, a composition, an article, or a component that is at least about 80%, at least about 85%, at least about 90%, at least about 91%, at least about 92%, at least about 93%, at least about 94%, at least about 95%, at least about 96%, at least about 97%, at least about 98%, at least about 99%, or about 100% by similar to the method, composition, article, or the component it is compared to.

As used herein, the term or phrase “effective,” “effective amount,” or “conditions effective to” refers to such amount or condition that is capable of performing the function or property for which an effective amount or condition is expressed. As will be pointed out below, the exact amount or particular condition required will vary from one aspect to another, depending on recognized variables such as the materials employed and the processing conditions observed. Thus, it is not always possible to specify an exact “effective amount” or “condition effective to.” However, it should be understood that an appropriate effective amount will be readily determined by one of ordinary skill in the art using only routine experimentation.

As used herein, the terms “substantially identical reference composition” or “substantially identical reference method” refer to a reference composition or method comprising substantially identical components or method steps in the absence of an inventive component or a method step. In another exemplary embodiment, the term “substantially,” in, for example, the context “substantially identical reference compositions,” refers to a reference composition or a method step that comprises substantially identical components or method steps, and wherein an inventive component or a method step is substituted with a common in the art component or a method step.

While aspects of the present invention can be described and claimed in a particular statutory class, such as the system statutory class, this is for convenience only and one of ordinary skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred in any respect. This holds for any possible non-express basis for interpretation, including matters of logic with respect to the arrangement of steps or operational flow, plain meaning derived from grammatical organization or punctuation, or the number or type of aspects described in the specification.

The present invention may be understood more readily by reference to the following detailed description of various aspects of the invention and the examples included therein and to the Figures and their previous and following description.

### Platforms

A novel operando scanning electron microscopy (SEM) platform that enables the first in situ imaging of dynamic fluid-rock interactions at the sub-micrometer scale to elucidate the impact of thermochemical transformation on waste storage security in argillaceous repositories was developed. Using the novel operando SEM platform, the nucleation and propagation of microfractures in the mineral matrix during heating to elucidate the thermal stress conditions necessary for fracture development can be visualized. Quantitative capabilities of the visual approach are validated by comparing imaging-based rates of organic matter pyrolysis with bulk measurements, where microscale compositional heterogeneity between organic solids is elucidated for the first time. Notably, operando wettability and organic matter decomposition characterizations here inform a set of thermal stress criteria such that thermogenic flow paths become self-sealed to promote long-term waste storage security.

In certain aspects, disclosed herein is an operando scanning electron microscopy platform comprising: a first cell comprising: (a) a sample well configured to receive a solid sample, for example having at least one dimension up to about 20 mm, about 2-10 mm, about 2-5 mm, about 2-20 mm, about 5-10 mm, about 5-15 mm, about 5-20 mm, about 5-25 mm, about 10-15 mm, about 10-20 mm, about 10-25 mm, about 10-30 mm, about 15-40 mm, about 20-50 mm, about 20-100 mm, or about 50-100 mm; and (b) one or more electron beam transparent coverings positioned above the solid sample; wherein the platform is sealed and configured to withstand a pressure up to about 10 MPa and a temperature up to about 500° C. In such exemplary and unlimiting aspects, the first cell can have any shape that can suit a scanning electronic microscope (SEM) chamber, or it can be adapted for use in an SEM. For example, and without limitations, the first cell can have a cubic, a cylinder, a cuboid shape, or any combination thereof. It is understood that these shapes are only exemplary, and any regular or irregular shapes can be adopted as long these platform shapes can be used with an SEM. Yet, in still further aspects, it is understood that the shape of the sample well can be similar to the shape of the first cell in general. Yet, in other aspects, the shape of the sample well can be different. In still further aspects, the shape of the sample well can be any shape configured to obtain the sample of the predetermined dimensions. For example, and without limitations, the shape of the first cell can be a cubic cell, while the sample well can have a cylindrical form. Yet, in other aspects, the shape of the first cell and the shape of the sample well can be cubic.

In still further aspects, it is understood that the sample well can be defined by at least two dimensions. For example, if the sample well has a cylindrical shape, such a sample well will be defined by a depth of the well and a diameter of the well. Yet in other aspects, if the sample well has a cubic or a cuboid shape, such a sample well can be defined by a depth of the well, the width and the length of the well. In still further aspects, at least one of the sample well dimensions can be up to about 20 mm, up to about 15 mm, up to about 10 mm, or up to about 5 mm. In yet still further aspects, the at least one of the sample well dimensions is about 1 mm to about 20 mm, including exemplary values of about 2 mm, about 5 mm, about 10 mm, and about 15 mm. In still further aspects, the at least one of the sample well dimensions can have a value or a range of values between any two mentioned above values. For example, and without limitations, the at least one of the sample well dimensions can be about 5 mm to about 20 mm, or about 5 mm to about 10 mm, or about 10 mm to about 20 mm. In some aspects, the at least one of the sample well dimesions can be from about 2-10 mm, about 2-5 mm, about 2-20 mm, about 5-10 mm, about 5-15 mm, about 5-20 mm, about 5-25 mm, about 10-15 mm, about 10-20 mm, about 10-25 mm, about 10-30 mm, about 15-40 mm, about 20-50 mm, about 20-100 mm, or about 50-100 mm

In still further aspects, at least two of the dimensions of the sample well can fall within mentioned above values. Yet in still further aspects, at least three of the dimensions of the sample well can fall within mentioned above values. In aspects where the sample well is defined by more than one dimension, all the dimensions can have the same value, or they can have different values within the disclosed above ranges. In yet still, in further aspects, the at least one dimension that is up to about 20 mm is the depth of the sample well. In yet still further aspects, the sample well in the disclosed herein aspects has a depth up to about 20 mm, up to about 15 mm, up to about 10 mm, or up to about 5 mm. In yet still further aspects, the depth of the sample well can be about 1 mm to about 20 mm, including exemplary values of about 2 mm, about 5 mm, about 10 mm, and about 15 mm. In still further aspects, the depth of the sample well can have a value or a range of values between any two mentioned above values. For example, and without limitations, the depth of the sample well can be about 5 mm to about 20 mm, or about 5 mm to about 10 mm, or about 10 mm to about 20 mm. In some aspects, the depth of the sample well can be from about 2-10 mm, about 2-5 mm, about 2-20 mm, about 5-10 mm, about 5-15 mm, about 5-20 mm, about 5-25 mm, about 10-15 mm, about 10-20 mm, about 10-25 mm, about 10-30 mm, about 15-40 mm, about 20-50 mm, about 20-100 mm, or about 50-100 mm

In still further asepcts, the platform disclosed herein can be sealed and be configured to withstand a pressure of up to about 10 MPa, up to about 8 MPa, up to about 6 MPa, up to about 5 MPa, and up to about 2 MPa. In still further aspects, the platform is configured to withstand a pressure in a range of about 1 MPa to about 10 MPa, about 2 MPa to about 10 MPa, about 5 MPa to about 10 MPa. It is understood that the platform is configured to withstand any pressures falling in any of the disclosed above ranges. For example, the platform is configured to withstand a pressure of about 1 MPa, about 2 MPa, about 3 MPa, about 4 MPa, about 5 MPa, about 6 MPa, about 7 MPa, about 8 MPa, about 9 MPa, and about 10 MPa.

In still further aspects, the platform is configured to withstand a temperature up to about 1,000° C., up to about 900° C., up to about 800° C., up to about 700° C., up to about 600° C., up to about 500° C., up to about 400° C.,° C., up to about 300° C., up to about 200° C., and up to about 100° C. In still further aspects, the platform is configured to withstand a temperature in a range of about −25° C. to about 500° C., or about −20° C. to about 500° C., about −10° C. to about 500° C., about 0° C. to about 500° C., about 10° C. to about 500° C., and so on. In some aspects, the platform is configured to withstand a temperature from about −25° C. to about 1,000° C., from about 0° C. to about 1,000° C., or from about 25° C. to about 1,000° C., It is understood that the platform is configured to withstand any temperature range that falls within the broadest temperature range disclosed herein. For example, the platform can withstand temperatures of about −25° C. to about 500° C., including exemplary values of about −20° C., about −15° C., about −10° C., about −5° C., 0° C., about 5° C., about 10° C., about 20° C., about 50° C., about 100° C., about 150° C., about 200° C., about 250° C., about 300° C., about 350° C., about 400° C., about 450° C., and about 499° C. It is further understood that the temperature can be between any of the values mentioned above. For example, and without limitations, it can be from about −15° C. to about 250° C., or from 0° C. to about 400° C., or from about −7° C. to about 475° C., and so on.

In still further aspects, the platform can withstand both pressure and temperature having any of the values or ranges of the values disclosed above.

In still further aspects, the sample well is configured to host a sample. The sample can be any solid sample having any dimensions that allow it to be positioned within the disclosed herein sample well. In certain aspects, the solid sample can be any sample whose interactions with other matters, such as fluids and gases, need to be operando visualized. In certain aspects, the solid sample can be a portion of a natural compound, or manufactured compound, or any combination thereof. In certain aspects, the solid sample can be porous. For example, and without limitations, the solid sample can be a portion of a porous shale structure. Yet in other aspects, the solid sample can be any natural or engineered porous material, an electrode, a solid catalyst, a plurality of particles, or any combination thereof. In still further aspects, the solid sample can have any dimensions suitable for the desired application. In still further aspects, the solid sample has dimensions that are compatible with the sample well dimensions.

In still further aspects, the sample well of the disclosed herein operando scanning electron microscopy platform is further configured to receive and host an amount of a fluid and/or gas, such that solid sample-fluid and/or solid sample/fluid interactions are monitored with a scanning electron microscope. It is understood that any gases or fluids that are suitable for the desired application can be utilized. In certain aspects, the fluids can be organic or inorganic solutions. Yet in other aspects, the sample well and the platform itself are designed to withstand harsh conditions, such as hosting at least an amount of acid and/or base. Yet in still further aspects, the sample well and the platform itself are designed to withstand harsh conditions, such as hosting at least an amount of reactive gas. Yet in other aspects, the fluids and gases can be non-reactive to the platform components but reactive or have specific interactions with the solid sample.

In still further aspects, the one or more electron beam transparent coverings comprise one or more one electron beam transparent membranes. In certain aspects, the platform can have one electron beam transparent coverings, such as, for example, one electron beam transparent membrane. In yet other aspects, the platform can have two or more electron beam transparent coverings, such as membranes positioned on each other. In still further aspects, the platform can comprise from 1 to 20 electron beam transparent membranes having any desired thickness from about 5 nm to about 100 μm thickness. In still further aspects, the platform can comprise from 1 to 5 electron beam transparent membranes, or from 1 to 10, or 2 to 15, or 1 to 15 electron beam transparent membranes, and so on. In still further aspects, the platform can comprise 1, 2, 3, 4, 5, 6, 7, 8, 9, 10, 11, 12, 13, 14, 15, 16, 17, 18, 19, and 20 electron beam transparent membranes. Yet in still further aspects, the platform can comprise a number of electron beam transparent membranes that fall a range formed by any two of the disclosed values. For example, and without limitations, the platform can comprise 1 to 9 electron beam transparent membranes, 3 to 1π electron beam transparent membranes, 1 to 11 electron beam transparent membranes, and so on.

In still further aspects, a thickness of each of the membranes can have any value or a range of the values with the disclosed above range. For example and without limitations, the thickness of the each of the membranes can be from about 5 nm to 100 μm, or from 10 nm to about 500 nm, or from about 30 nm to about 10 μm, or from about 100 nm to about 50 μm, or from about 30 μm to about 75 μm and so own. In still further aspects, the thickness of the each of the membranes can be about 5 nm, about 15 nm, about 30 nm, about 50 nm, about 100 nm, about 150 nm, about 500 nm, about 1 μm, about 30 μm, about 50 μm, and about 99 μm. In still further aspects, the thickness can have any value between any two of the disclosed values. In yet still further aspects, the thickness can fall within any range formed by any of the disclosed above values.

In still further aspects, the one or more electron beam transparent membranes comprise graphene, silicon nitride, or any combination thereof. In some aspects, at least one membrane comprises graphene. In yet other aspects, at least one membrane comprises silicon nitride.

In still further aspects and as disclosed above, the sample well is configured to receive and host a gas and/or fluid. In certain aspects, during the operando visualization process, various chemical reactions can occur. In such aspects, various reaction products can also be formed. The reaction products can have various states of matter, for example, the reaction products can be gaseous, liquid or solid. For example and without limitations, if organic matter decomposition is operando visualized using the disclosed herein platform, the reaction products are preserved inside the sample well by the one or more electron transparent membranes.

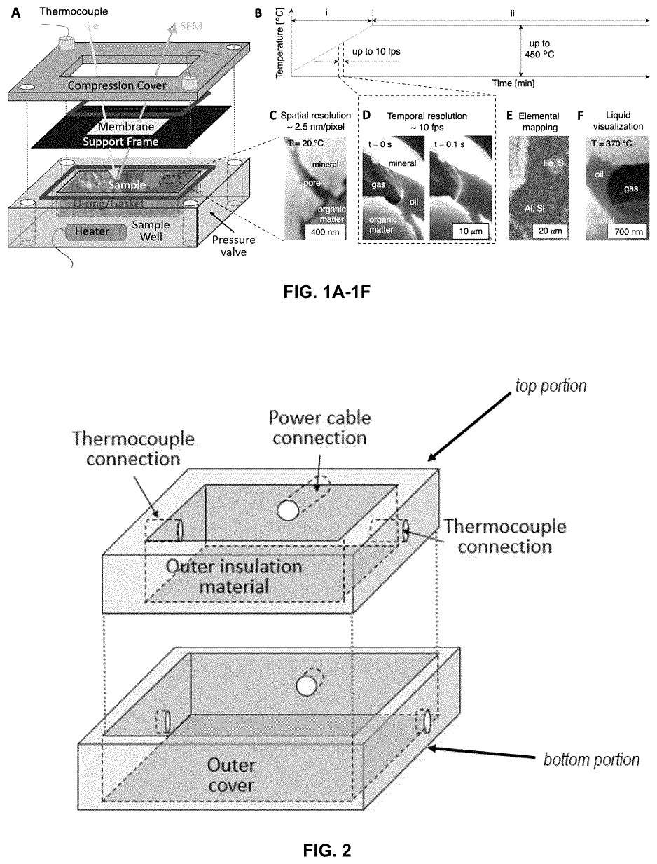

In certain aspects and as shown in FIG. 1A, the one or more electron beam transparent membranes can be positioned within the support frame. In such exemplary and unlimiting aspects, the support frame is positioned such that it at least partially covers the sample well. The support frame includes an opening that is configured to receive the one or more electron beam transparent membranes. The dimensions of the opening and the one or more transparent membranes can be determined based on the actual size of the first cell, the area that needs to be exposed to the electron beam, etc. The exposure can also be determined based on the size of the example and the studied phenomena to be visualized. In some exemplary and unlimiting aspects, the opening can have at least one dimension of about 500 microns to about 10 mm, or about 1 mm to about 5 mm, about 700 microns to about 3 mm, and the like. It is understood that the ranges provided above are exemplary, and the at least one dimension of the opening can be in any range between any two of the disclosed values. It is further understood that the opening can have any regular or irregular shape. For example, it can be circular, square, rectangular and so on. In still further aspects, the frame can be made from any material that is suitable for the desired operation. It is understood that the frame is made of a material that can withstand the conditions described herein and can be compressible to allow a good seal of the platform. In still further aspects, the support frame can have any thickness in any range from about 1 μm to about 1 mm, including exemplary ranges of about 1 μm to about 500 μm, or about 1 μm to about 250 μm, or about 1 μm to about 200 μm, and so on. It is further understood that the thickness of the support frame can have any values or fall within any range of values between any two of the disclosed above values.

In still further aspects, the one or more electron transparent membranes can be formed by any known in the art methods. In certain aspects, the one or more membranes are positioned within the frame opening. While in other aspects, the one or more membranes can be deposited within the support frame.

Still further and as also shown in FIG. 1A, the first cell is sealed. In such aspects, the sample well and the one or more electron beam transparent coverings are sealed against each other with a compression cover. In still further aspects, any methods of sealing the first cell can be utilized. For example, the first cell can further comprise a cover lid. The cover lid, the support frame, and the sample well can be sealed using gaskets if needed.

In still further aspects, when the solid sample is positioned within the sample well, a tight contact is formed between the solid sample and the one or more electron beam transparent coverings.

In still further aspects, the sample well can comprise a thermostable bed positioned at a bottom of the well. In certain aspects, the solid sample is positioned on the thermostable bed. In still further aspects, a thickness of the thermostable bed is adjustable to ensure tight contact between the solid sample. In still further aspects, the thermostable bed can be chosen for a desired application. The thermostable bed can comprise, for example, elastic thermostable wool.

In still further aspects, and as schematically shown in FIG. 1A, the first cell can comprise one or more orifices configured to receive one or more temperature measuring devices, an electrical connection, heating/cooling elements, a flow of a gas or a fluid, a tubing, or any combination thereof. In still further asepcts, the first cell can comprise one or more valves that are configured to regulate pressure, flow of the gas or the liquid, and so on. In still further aspects, the one or more orifices are in communication with the sample well. For example, the cover lid can have one or more orifices configured to receive, for example, and without limitations, a temperature measuring device. This temperature-measuring device can be inserted into the sample well if needed. Yet in other aspects, the orifices can be present in a portion of the first cell that hosts the sample well.

In still further aspects, the platform can comprise a second cell. The second cell can effectively encompass the first cell, wherein the second cell is at least partially thermally insulating the first cell. The exemplary second cell is shown in FIG. 2. In such exemplary and unlimiting aspects, the second cell can comprise a bottom portion and a top portion. In such exemplary aspects, the top and bottom portions can be reversibly sealed.

In still further aspects, the bottom portion of the second cell is configured to at least house the sample well. In such aspects, the bottom portion of the second cell can have a predetermined wall thickness designed to allow the desired thermal insulation. In some aspects, the bottom portion of the second cell is comprised of a stainless steel, ceramic material, metal alloy, polymer, or a combination thereof.

In still further aspects, the top portion of the second cell is positioned around a top portion of the first cell such that the least the one or more electron beam transparent coverings are not obscured from an electron beam of a scanning electron microscope. In still further aspects, the top portion of the second cell has an opening that is compatible with the opening of the first cell and allows penetration of the electron beam of the microscope to reach the sample well.

In still further aspects, the top portion of the second cell further thermally insulates the first cell. In still further aspects, the top portion of the second cell is configured to insulate the first cell from one or more scanning electron microscope detectors. It is understood that in some aspects, the top portion of the second cell can be formed from the same material as the bottom portion of the second cell. Yet in other aspects, the top portion of the second cell can be formed from the different materials used to form the bottom portion of the second cell. In still further aspects, the top portion of the second cell can comprise a thermal insulating material, for example a ceramic material, metal alloy, polymer, or combination thereof. In still further aspects, the first cell and/or the second cell comprises materials that exhibit shielding against magnetic fields and X-rays. In still further aspects, each part of the disclosed herein platform can be made by any known in the art methods. For example, in some aspects, at least some parts of the platform can be made by precise machining of the desired materials or by 3D-printing, etc.

In still further aspects, the second cell can further comprise one or more orifices configured to receive one or more thermal devices, an electrical connection, a gas or a fluid flow, a tubing, or any combination thereof. In still further aspects, the one or more orifices of the second cell are in communication with the first cell. In yet other aspects, the one or more orifices of the second cell are in communication with the one or more orifices of the first cell. It is understood that the one or more orifices of the second cell can be positioned anywhere to ensure the desired application. In certain aspects, the one or more orifices of the second cell are positioned at the top portion, bottom portion, or both.

In still further aspects, the first cell is positioned within the second cell such that at least some spacing is formed between an outer surface of the first cell and an inner surface of the second cell. In still further aspects, the spacing can further comprise an insulating material. Any insulating materials known in the art can be used for such purposes.

In still further aspects, and as shown in FIG. 1A the platform can also comprise and/or be in communication with one or more heating devices. In still further aspects, the platform can also comprise and/or be in communication with one or more cooling devices. In some aspects, the heating and/or cooling device can be embedded anywhere within the platform. In some exemplary and unlimiting aspects, the heating and/or colling device can be embedded in a wall thickness of the first cell in proximity to the sample well. In yet further aspects, the heater/cooling device can be embedded in the spacing between the first cell and the second cell. Yet in other aspects, the heating and/or cooling device can be positioned outside of the platform and be in electrical communication with the platform.

As discussed above, disclosed herein are aspects where the platform is in communication with one or more pressure relief valves. In still further aspects, the disclosed herein platform is in communication with a temperature-measuring device, such as a thermocouple, for example. It is understood that the temperature can also be measured by other known in the art means. In still further aspects, if the platform is used to visualize electrochemical processes, the platform can be in communication with a potentiostat or, a galvanostat, or any other appropriate device. In still further aspects, the platform can operate as a flow cell. In some aspects, the platform allows to visualize processes that occur both in a steady state and in an equilibrium if desired.

In still further aspects, the platform is in communication with one or more controllers. It is understood that in certain aspects, the communication with the one or more controllers can be wireless. Yet, in other aspects, the communication can be achieved through electrical connections.

In still further asepcts, the one or more controllers can be characterized as having general-purpose inputs and outputs that are connected to appropriate processors, computerized memory, and hardware that is appropriate for customized machine logical operations.

In still further aspects, the controllers can be or be in communication with computing devices. Examples of well-known computing devices, environments, and/or configurations that can be suitable for use include, but are not limited to, personal computers, server computers, handheld or laptop devices, smartphones, multiprocessor systems, microprocessor-based systems, network personal computers (PCs), minicomputers, mainframe computers, embedded systems, distributed computing environments that include any of the above systems or devices, and the like.

Computing devices, as disclosed herein, can contain communication connection(s) that allow the device to communicate with other devices if desired. Computing devices can also have input device(s) such as a keyboard, mouse, pen, voice input device, touch input device, etc. Output device(s) such as a display, speakers, printer, etc., can also be included. All these devices are well-known in the art and need not be discussed at length here.

Computer-executable instructions, such as program modules being executed by a computer, can be used. Generally, program modules include routines, programs, objects, components, data structures, etc., that perform particular tasks or implement particular abstract data types. Distributed computing environments can be used where tasks are performed by remote processing devices that are linked through a communications network or other data transmission medium. In a distributed computing environment, program modules and other data can be located in both local and remote computer storage media, including memory storage devices.

In its most base configuration, a computing device typically includes at least one processing unit and memory. Depending on the exact configuration and type of computing device, memory can be volatile (such as random-access memory (RAM)), non-volatile (such as read-only memory (ROM), flash memory, etc.), or some combination of the two.

Computing devices can have additional features/functionality. For example, a computing device can include additional storage (removable and/or non-removable), including, but not limited to, magnetic or optical disks or tape.

Computing device typically includes a variety of computer-readable media. Computer-readable media can be any available media that can be accessed by the device and includes both volatile and non-volatile media, removable and non-removable media.

Computer storage media include volatile and non-volatile and removable and non-removable media implemented in any method or technology for information storage, such as computer-readable instructions, data structures, program modules, or other data. Memory, removable storage, and non-removable storage are all examples of computer storage media. Computer storage media include but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computing device. Any such computer storage media can be part of a computing device.

Computing devices, as disclosed herein, can contain communication connection(s) that allow the device to communicate with other devices. The connection can be wireless or wired. Computing devices can also have input device(s) such as a keyboard, mouse, pen, voice input device, touch input device, etc. Output device(s) such as a display, speakers, printer, etc., can also be included. All these devices are well-known in the art and need not be discussed at length here.

It should be understood that the various techniques described herein can be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, can take the form of program code (i.e., instructions) embodied in tangible media, such as CD-ROMs, hard drives, or any other machine-readable storage medium where, when the program code is loaded into and executed by a machine, such as a computer, the machine becomes an apparatus for practicing the presently disclosed subject matter.

In still further aspects, the one or more controllers are Bluetooth operated.

In still further aspects, the one or more controllers can comprise a firmware that can be adapted for use with the platform and an electron microscope.

In still further aspects, the one or more controllers are configured to heat (and/or cool) the sample well to a predetermined temperature at a predetermined rate. In still further aspects, the one or more controllers are configured to heat (and/or cool) the sample well in the desired temperature pattern.

In still further aspects, the platform is configured to allow the sample operando visualization with a spatio-chemical resolution of about 1 nm/pixel to about 50 nm/pixel, including exemplary ranges of about 1 nm/pixel to about 25 nm/pixel or about 2.5 nm/pixel to about 30 nm/pixel and so on. It is further understood that the resolution can have any value between or any range of values that falls within the disclosed broadest range. In still further aspects, the platform is configured to allow the sample operando visualization with a temporal-chemical resolution of up to about 10 fps.

In still further aspects, the disclosed herein operando scanning electron microscopy platform can be adapted to use with additional detectors commonly used with SEMs. For example and without limitations, the disclosed herein operando scanning electron microscopy platform can be adapted for energy-dispersive X-ray spectroscopy (EDS) elemental mapping.

Also disclosed herein is an electron microscope comprising a chamber configured to receive the disclosed herein operando scanning electron microscopy platform.

### Methods

Also disclosed herein is a method of operando visualization of various chemical and physical interactions for a deeper understanding of mechanistic processes. In some aspects, disclosed herein is a method comprising positioning the disclosed herein operando scanning electron microscopy platform comprising a solid sample having at least one dimension up to about 20 mm in an electron microscope chamber; optionally heating (or cooling) and/or pressuring the sample to a temperature up to about 500° C. and/or pressure of 10 MPa; and imaging the solid sample.

In still further aspects, the imaging can be continuous, or it can be done on demand. In still further aspects, the imaging process can be controlled by an SEM or by the one or more controllers disclosed herein.

In still further aspects, if the heating step is present, such heating can be done, for example, according to a non-isothermal ramp-up stage. However, it is understood that the heating and/or cooling pattern can be determined based on the desired phenomena to be studied. In yet still further aspects, the methods disclosed herein can comprise measurements of thermo-chemo-mechanical phenomena of the solid sample. Yet in other aspects, the method can comprise measurements of the wettability of the solid sample. The methods disclosed herein allow the sample visualization with a spatio-temporal-chemical resolution of about 1 nm/pixel to about 50 nm/pixel and up to about 10 fps. In still further aspects, if the measurement of the elemental content is also desired, the method can comprise an energy-dispersive X-ray spectroscopy (EDS) elemental mapping of the sample.

### EXAMPLES

The following examples are put forth so as to provide those of ordinary skill in the art with a complete disclosure and description of how the compounds, compositions, articles, devices and/or methods claimed herein are made and evaluated and are intended to be purely exemplary and are not intended to limit the disclosure. Efforts have been made to ensure accuracy with respect to numbers (e.g., amounts, temperature, etc.), but some errors and deviations should be accounted for.

Unless indicated otherwise, parts are parts by weight, temperature is degrees C. or is at ambient temperature, and pressure is at or near atmospheric or full vacuum.

Current approaches to recover REEs from fly ash are challenged by a limited understanding of the fundamental particulate material properties and reactive transport processes. Distinct transport and reactive phenomena take place at the sub-particle-level during REEs recovery treatments. The inventors found that crystallinity strongly impacts the reactivity and ion diffusivity of material phases, and the results are shown here.

### Microscale Imaging via ESEM-EDS

In situ SEM imaging. Operando imaging of in situ fluid-mineral interactions was performed inside a high vacuum scanning electron microscope (FEI Quanta 650 ESEM, high vacuum ˜10⁻⁴ to 10⁻⁵ torr). The SEM was equipped with Everhart-Thornley detection (ETD) and energy dispersive X-ray spectroscopy (Bruker EDX). ETD was used for direct in situ visualization of organic matter thermolysis, fluid-mineral interactions, and matrix micro-fracturing under thermal stress. EDS spectroscopy was used for elemental mapping and mineral phase identification. Both ETD direct visualization and EDX elemental mapping of the pore morphology and connectivity of shale samples were achieved at a voltage of 30 kV. The spot size diameter used for imaging was ˜6 to 7 nm. Operando visualization was achieved for experiments conducted at the temperatures ranging from 20° C. to 450° C.

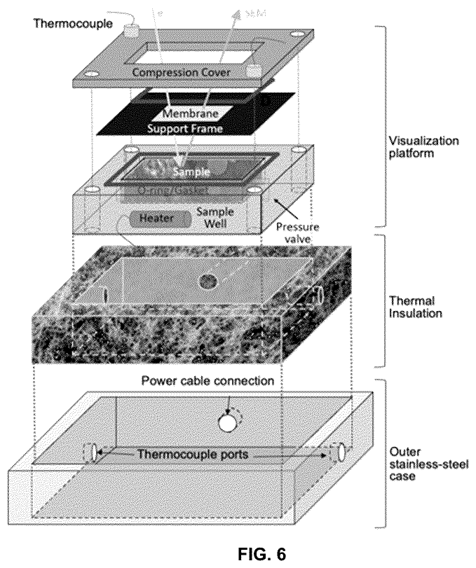

Platform design. High temperature in situ imaging is enabled by inserting the visualization platform that isolates the fluid/solid sample from the SEM vacuum (FIG. 1) in an outer insulation case (FIG. 6). Thermal insulation is achieved by a 15 mm thick layer of ceramic material (Alumina Ceramic, McMaster-Carr) that is held to the main visualization platform by an exterior stainless-steel case (FIG. 6). The exterior cell thermally insulates the visualization platform from chamber detectors and the microscope stage. The maximum temperature of the outer stainless steel case was ˜80° C.

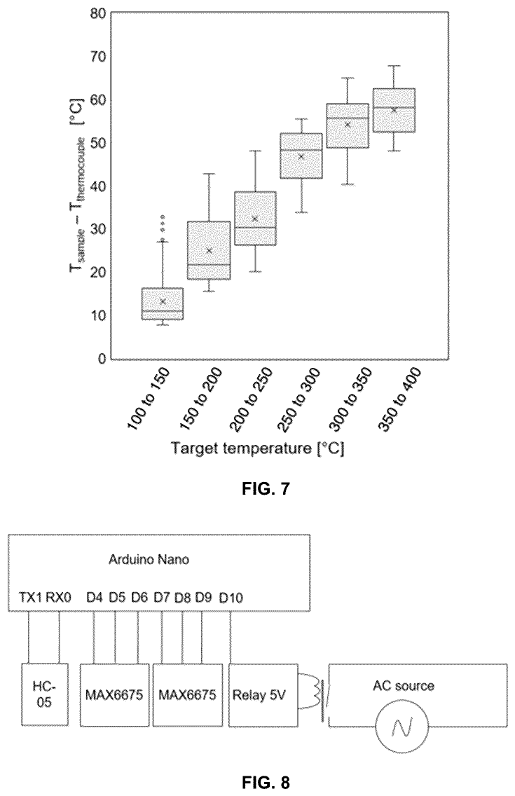

Operando temperatures of the shale sample was measured using a pair of K-type thermocouples that are attached to the compression cover of the visualization platform. Spatial variations in temperature measurements at the sample and the thermocouples (thermocouples are ˜12 mm away from the material sample) are accounted for by calibrating the thermocouple data with direct temperature measurements taken on the sample (in vacuum, without visualization). Temperature measurements presented in the main text were adjusted using this calibration data (FIG. 7).

Circuitry for the Arduino thermal control board is shown in FIG. 8. A Tech HC-5 Bluetooth Serial Pass-through Module is connected to ports TX1 and RX0. Ports D4 through D10 are used to connect thermocouples. D10 is used for Relay connection.

Organic matter characterization. Organic matter composition of the shale samples was measured using pyrolysis (HAWK). Samples were heated to temperatures of ˜600° C. Gas phase reaction products from thermochemical decomposition reactions were measured in the presence of an inert helium gas. Organic matter is categorized as S1 or S2. S1 refers to the free hydrocarbons in the shale sample that are vaporized below temperatures of ˜300° C. S2 refers to the organic material that becomes converted to hydrocarbon fluids with thermal pyrolysis. We measure Tₘₐₓ (i.e., temperature at which the maximum kerogen pyrolysis occurs) as an indicator for the maturity of the shale sample. Here, the Tₘₐₓ occurs at a temperature of ˜432 to 434° C., indicating an immature/mature shale. Total organic carbon measures the sum of residual organic carbon and pyrolyzed organic carbon. Hydrogen and oxygen indices (HI, OI) were calculated to characterize the origin of the organic material; the high HI and low OI indicate marine origin for the shale samples used in this study.

### Example 1

### Methods

A middle-Devonian shale from Central Ohio was used in this study. Hydrocarbon (HC) composition of the sample, characterized using flame ionization detection (FID), showed that ˜2.64 to 2.68 mg_{HC}/g_{rock} was released via thermal desorption (S1 peak) whereas pyrolysis generated ˜55.8 to 56.9 mg_{HC}/g_{rock} (S2 peak). The total organic content of this sample was 7.9 to 8.0 wt. %, consistent with the organic content of the Boom clays. For this sample, the maximum rate of hydrocarbon generation was at a temperature of Tₘₐₓ=434±1° C., with a hydrogen index (HI) of 707 to 720 and oxygen index (OI) of 3 to 4:

HAWK-Eye Analysis Report

| Pyrolysis data | Range |
|---|---|
| Free Oil, S1 (mg_{HC}/g_{rock}) | 2.64 to 2.68 |
| Kerogen yield, S2 (mg_{HC}/g_{rock}) | 55.84 to 56.9 |
| Kerogen maturity, Tₘₐₓ (° C.) | 432 to 434 |
| CO₂ yield during kerogen pyrolysis, S3 (mg_{CO2}/g_{rock}) | 0.22 to 0.24 |
| Total Organic Carbon, TOC (wt. %) | 7.9 to 8.1 |
| Hydrogen Index, HI (mg_{HC}/g_{TOC}) | 707 to 720 |
| Oxygen Index, OI (mg_{CO2}/g_{TOC}) | 3 to 4 |

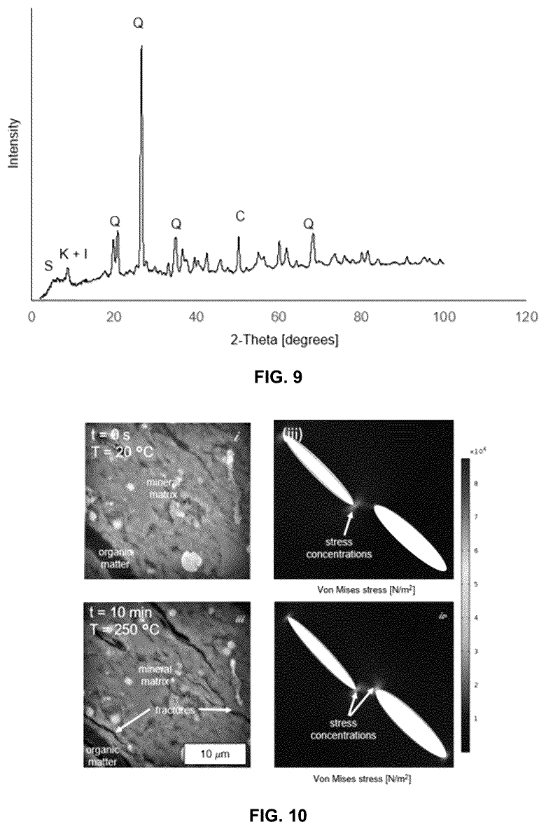

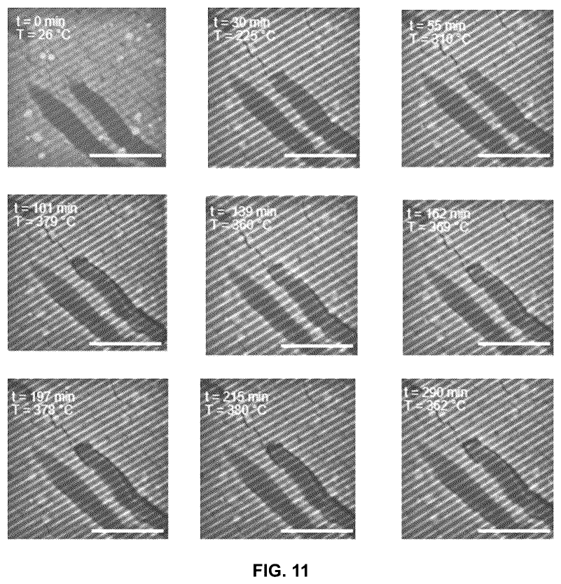

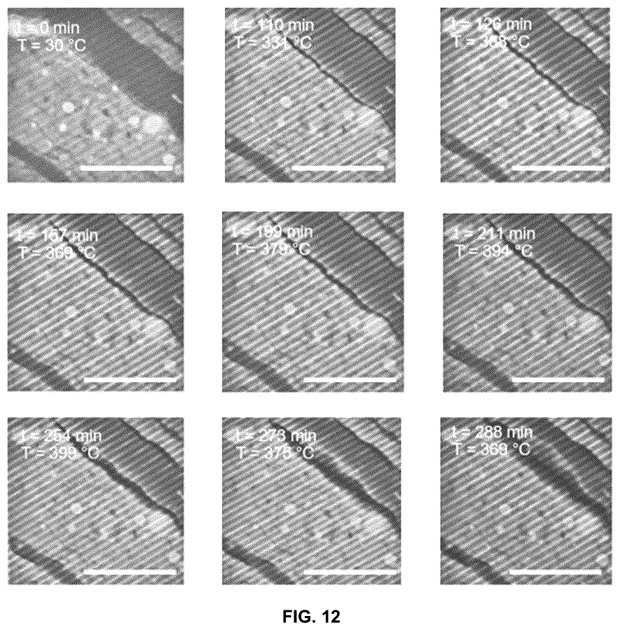

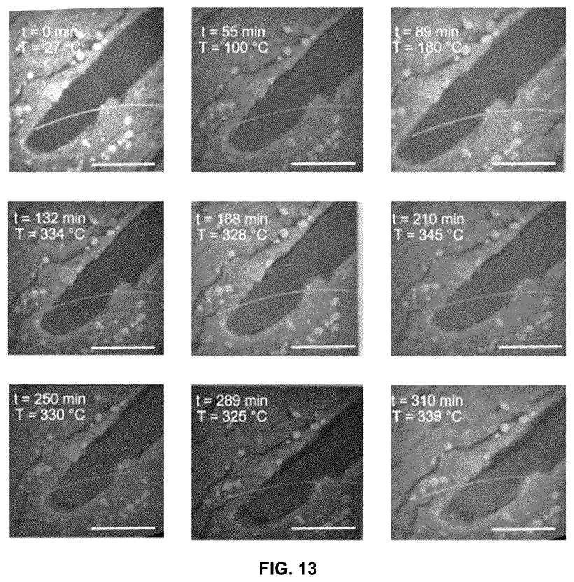

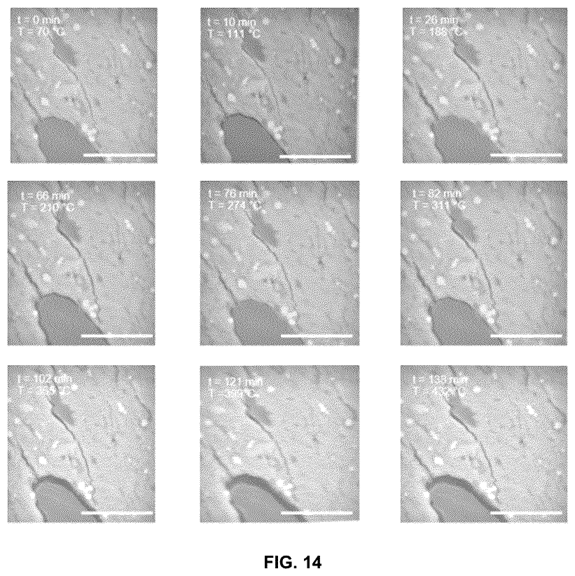

Mineralogy characterization using X-ray diffraction (XRD, Rigaku R-Axis Spider) showed that the sample was comprised primarily of quartz, illite, kaolinite, and smectite (FIG. 9):

Shale sample mineralogy measured using X-ray diffraction (XRD)

| | Mass fraction |
|---|---|
| Phase | (wt. %) |
| Quartz | 25.6 |
| Clays (kaolinite, illite, smectite) | 52.1 |
| Remaining phases (calcite, rutile, muscovite, pyrite) | 22.3 |

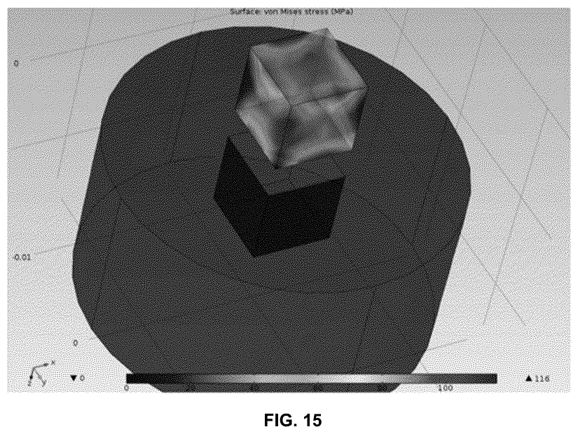

Once collected and characterized, shale samples were cut into 1×1×1 cm cubes and polished mechanically using a fine suspension with a particle size of 0.06 μm (TedPella). Polished samples were ion-milled (Leica TIC020 Ion Miller) to achieve a smooth surface for imaging. For non-isothermal experiments (dT/dt>0) where fractures were induced, samples were cut to ˜6 mm×6 mm×7 mm such that no compression stresses were applied from the sample well. Here, a pressure relief valve was used to constrain the in situ pressure in the platform. For high temperature isothermal experiments (dT/dt˜0) where kerogen thermolysis occurred, the samples were cut to ˜6.95 mm×6.95 mm×7 mm to 6.99 mm×6.99 mm×7 mm to provide confining stress during heating. Specifically, we leverage the differential thermal expansion coefficients for stainless steel (17.2×10⁻⁶° C.⁻¹) and shale (˜20×10⁻⁶° C.⁻¹) to confine the shale sample. Here, the average internal stress of the sample was ˜50 MPa during high temperature isothermal heating experiments (FIG. 15). Before each experiment, a thin layer of gold was deposited on the material samples to minimize surface charging during SEM imaging (EMS Sputter Coater).

Fluid-solid interactions were imaged directly in a scanning electron microscope (FEI Quanta 650) with energy dispersive X-ray spectroscopy (EDS) and Everhart-Thornley detection (ETD) by inserting the prepared samples in the stainless steel sample well of the operando SEM cell. The material samples were isolated from the SEM vacuum chamber by a SiNₓ membrane (Ted Pella). Two types of membranes were used here: a 9 window Si frame where each membrane window is 50 μm×50 μm×15 nm, and a Si frame with a single SiNₓ membrane window that is 150 μm×50 μm×35 nm. To seal the sample inside the operando platform, two copper gaskets (thickness˜200 μm) are compressed between the compression cover, the membrane, and the sample well.

Thermal control at elevated temperatures was enabled by inserting the platform assembly into an outer insulation cell (FIG. 6). Heating is delivered to the material sample using an 80 W cartridge heater (Insertion heater, McMaster-Carr) that is coupled to two K-type thermocouples (FIGS. 6, 8). Thermocouple data are calibrated for vacuum conditions (FIG. 7). Feedback control between the thermocouples and the heater is enabled using an Arduino nano control breadboard with a MAX6675 chip for thermocouple connection and a 5 V relay (CozParts). The platform assembly is equipped with a Bluetooth chip (Tech HC-5 Bluetooth Serial Pass-through Module, DSD TECH) that enables remote access during imaging to set the heating rates, target temperatures, and power applied to the heaters.

Reaction kinetics measured using the time-resolved imaging data were compared with thermogravimetric analyses (TGA, Mettler Thermogravimetric Analyzer Model TGA/DSC 1). Powdered shale samples were heated following the schema used in the operando SEM experiments. Heating rates from 3 to 10° C./min were applied to evaluate the effects of non-isothermal heating. Isothermal experiments were performed at temperatures ranging from 250° C. to 450° C. to establish residual heating loads imposed by nuclear waste decay.

The disclosed operando platform enables in situ imaging of dynamic fluid-rock interactions. In the disclosed herein examples, coupled chemo-mechano-hydrodynamic processes in shale under thermal stress were visualized. In this unlimiting example, the heating is delivered to the material sample using an 80 W cartridge heater coupled to two K-type thermocouples and a remote Bluetooth control system. Thermocouples data are calibrated for vacuum conditions. The platform heating experiment is programmed and controlled by a nano-control breadboard. The platform is equipped with a Bluetooth chip that controls the board and experiments remotely. The temperature data is sent to the controlling computer, and the control breadboard enables to change of heating parameters during the experiment. The control board enables to control of the parameters of the two stages separately by setting up the heating rate, target temperature, and power applied to the heater.

The gaseous and liquid reaction products of organic matter decomposition are preserved inside the sample well by an electron-transparent SiNₓ membrane. The membrane window (TedPella) can be fabricated by SiNₓ deposition on a 3 mm in diameter and 200 μm thick silicon frame that supports the membrane window. In this example, two membrane types were used: i) 9 windows, 50×50 μm with 15 nm thick membrane windows on silicon frame for heating experiment (type I) and a single window with 30 μm thick SiNₓ window on silicon frame for post-heating visualization (type II). The cover lid and silicon frame were sealed by two 200 μm copper gaskets. SiNₓ window is replaced after each experiment to ensure the containment of liquid and gaseous phases from the vacuum chamber. The sample is made out of a milled rock sample by cutting to a 6 mm by 6 mm by 6 mm block that is embedded into the 7 mm by 7 mm by 7 mm sample well. Between the sample and sample well bottom 1 mm thick layer of elastic thermostable wool was placed to ensure tight contact between the sample and membrane.

The platform is amenable to elemental composition mapping energy dispersive X-ray spectroscopy to elucidate the influence of mineralogy and surface chemistry on fluid-solid interactions. The platform enables the first direct visualization of fluid-rock interactions and wetting characteristics at elevated temperatures to elucidate radionucleotide transport mechanisms in argillaceous repositories. Moreover, direct in situ visualization enables the demonstration of fracture propagation in the presence of passive confinement pressure as a response to the thermal shock in a wide range of heating rates. A remote control allows to perform, theoretically, isothermal experiments with unlimited duration to study low-elevation temperature conditions. The platform also enables the characterization of the wetting properties of newly developed surfaces in ambient temperature mode to avoid phase change of the water. The disclosed herein operando SEM platform enables direct observation of in situ fluid-solid interactions in micro and nanoporous rock. The platform enables fluids and gas containment and direct visualization using ETD and EDS detectors under thermal chemical conversion representing natural geological processes. The platform enables direct element mapping through the SiNₓ membrane to capture spatial organic matter and mineralogical composition distribution.

### Example 2

A novel operando platform is developed that allows the first in situ SEM imaging of dynamic fluid-solid interactions in nanoporous materials (FIG. 1). The platform helps isolate wetted geologic samples from SEM vacuum environments while enabling direct electron beam probing. Function of the platform is enabled by its three main components (FIG. 1A): (i) a sample well (5 mm×5 mm×8 mm in depth) that holds the wetted material sample; (ii) an electron-transparent membrane (e.g., silicon nitride SiNₓ) that encloses the sample within the sample well while maintaining electron beam transmission; and (iii) a compression cover with O-rings and/or gaskets that isolates the wetted rock sample (>1 atm) from the SEM vacuum environment (˜10⁻⁷ torr).

The novel platform enables operando imaging of dynamic fluids-rock interactions at elevated temperatures (FIG. 1B) with spatial resolutions down to ˜2.5 nm/pixel (FIG. 1C) and temporal resolutions up to ˜10 fps (FIG. 1D). Spatially-resolved mapping of elemental species is enabled by SEM energy dispersive X-ray spectroscopy (SEM-EDS, FIG. 1E) to inform the progress of thermochemical reactions. For the first time, nanoscale pore-level liquid/gas/solids interfaces are resolved dynamically in situ (FIG. 1F). Fluid pressures are maintained by the SiNₓ membrane (Young's modulus˜280 to 290 GPa) (18) and a pressure relief valve. Thermal control up to ˜450° C. with non-isothermal (FIG. 1B, i, ΔT/Δt>0) and isothermal modulation (FIG. 1B, ii, ΔT/Δt˜0) is enabled using a cartridge heater, thermocouple, PID Bluetooth system (see SI). Notably, the self-contained platform system operates independently of feed-throughs and is functional in any SEM without the need for modification.

### Thermogenic Fracture Development

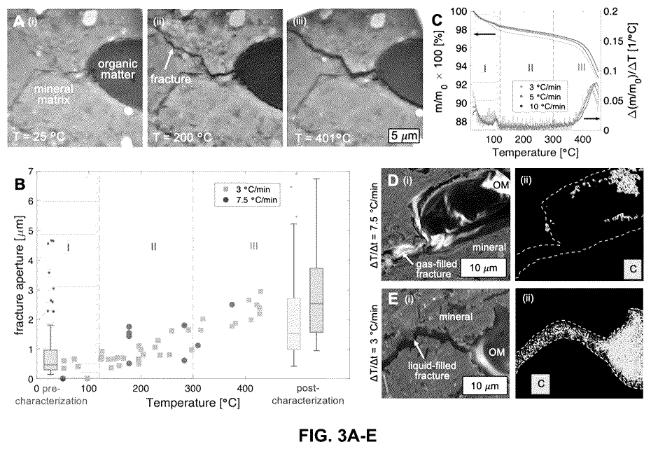

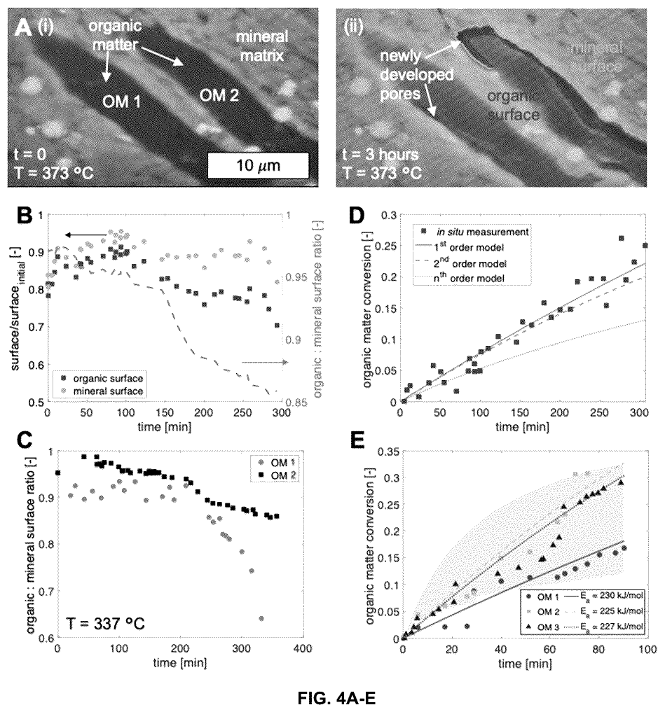

The utility of the operando SEM platform was demonstrated by imaging in situ thermochemical fracture and pore development in organic-rich shales (FIGS. 3, 4). Here, a shale sample comprised primarily of quartz and clay minerals (FIG. 3A, light gray material) with organic matter fragments (FIG. 3A, dark gray material) is imaged during heating up to ˜450° C. The organic solids in this sample comprise short-chain molecules that vaporize into hydrocarbon gases at low temperatures (T<300° C., FIG. 3B, C, II, blue shaded region) and heavy components that thermolyze into hydrocarbon fluids at elevated temperatures (i.e., T>300° C., FIG. 3B, C, III, yellow shaded region). Capillarity-bound water is vaporized at temperatures below ˜120° C. (FIG. 3B, C, I, pink shaded region).

During non-isothermal heating (dT/dt˜3, 7.5° C./min), microfractures begin to nucleate and propagate at temperatures of ˜120° C. (FIG. 3). Comparison with thermogravimetric analyses (TGA) show that fracture generation occurs during the vaporization of light hydrocarbons (FIGS. 3B, C, region II, T>120° C.) rather than that of capillarity-bound water (FIGS. 3B, C, region I, T<120° C.). We note, however, that water vaporization may contribute to local pressure buildup and ultimately matrix fracturing, although the samples here held no significant pore water initially (˜1 wt. %).

In all cases observed in this work, microfractures nucleate at the curved organic/mineral interface and propagate into the mineral matrix (FIG. 3A). This pattern of fracture nucleation and propagation suggests stress concentration at the organic/mineral interface. We note here that light hydrocarbon vapors are generated at a rate that exceeds its ability to diffuse into the surrounding silicates matrix (permeability˜nD) during rapid heating (e.g., dT/dt˜3 and 7.5° C./min). As a result, hydrocarbon vapors are instead trapped in and pressurize its parent organic structure. The resulting stress is concentrated at the curved tips of the organic/mineral interface where failure and fracturing initiate.

In the context of waste containment, microfracture propagation into the mineral matrix provides a set of high permeability pathways for fluid transport. The presence of generated hydrocarbon fluids (gases and liquids) within the microfractures, however, influence significantly the advective leakage potential of aqueous radionuclides. For fast heating rates (e.g., dT/dt=7.5° C./min) where heat conduction through the organic fragment is slow compared to the heat influx from the continuous mineral matrix, hydrocarbon vapors are generated and result in gas-saturated fractures that allow water imbibition. On the other hand, fractures generated during low-rate heating (e.g., dT/dt=3.5° C./min) are saturated with hydrocarbon liquids that potentially impede water convection. These complex multiphase fluid dynamics are important considerations in the selection of sites appropriate for nuclear waste disposal.

For temperatures exceeding the thermolysis threshold of organic solids in the sample (T>˜300° C.), isothermal heating leads to pore development at the organic-mineral interface (FIG. 4). Here, a shale sample with organic matter fragments (FIG. 4A, i) is subjected to heating at 373° C. for 3 hours. Time-resolved image sequences show that thermolytic pore creation begins at the organic-mineral interface (FIG. 4A, ii) and propagates into the organic solid. Specifically, thermogenic pores begin as thin gaps between the organic and mineral phases with organic-to-mineral surface ratios close to unity (FIG. 4B, C, t=0 to 100 min). Sustained organic solids thermolysis at elevated temperatures leads to the inward development of pores (i.e., into the organic solid) and decreasing organic-to-mineral surface ratios (FIG. 4B, C, t>100 min). Evolving ratios of organic and mineral surfaces here, each described by distinct wetting and sorption characteristics, contribute potential changes to the multiphase transport (e.g., relative permeability) of aqueous radionuclides. Compositional heterogeneities between organic fragments, interestingly, give rise to differential rates of organic surface generation (FIG. 4C).

Quantitative capabilities of the operando visualization platform are demonstrated by comparing in situ image sequences of micro/nanoscopic organic fragment thermolysis to bulk characterizations. As in bulk pyrolysis measurements, quantification of in situ imaging shows that the thermolytic reaction rates for individual organic fragments are best described using a first-order reaction model (FIG. 4D):

$$\frac{d [ OM ]}{d t} = - {k [ OM ]}^{n}$$

where the decomposition rate of organic matter, OM, decays exponentially over time as n=1. Here, the kinetics, k, are described by the Arrhenius equation:

$$k = A {e}^{- {E}_{a} / R T}$$

where the pre-exponential factor A=1.5×10¹⁴ s⁻¹ and activation energy Eₐ=230 kJ/mol are taken from bulk characterizations reported in the literature. The temperature is T=373° C. and corresponds to the in situ experimental conditions. Despite identical thermal stressing (i.e., from the same experiment), we note that organic fragments adjacent to one another experience differential rates of thermal decomposition (FIG. 4A, E). These fragment-specific differences are captured by distinct activation energies Eₐ (FIG. 4E, E_{a,1}=230 KJ/mol, E_{a,2}=225 KJ/mol, E_{a,3}=227 KJ/mol) that may reflect heterogeneities in molecular composition (FIG. 4E, lines). For each organic fragment, the imaging-based rates of thermolysis at 373° C. (FIG. 4E, data points) and first-order reaction models (FIG. 4E, lines) are consistent with bulk reaction rates measured using TGA for temperatures between 350° C. and 400° C. (FIG. 4E, green shaded region).

We note here that the fractures and pores observed at organic-mineral interfaces are not a result of thermal contraction as postulated in previous investigations. Whereas inconclusive results in the literature stem from the experimental uncertainties of ex situ characterization, our operando experiments prove conclusively that for relatively high rates of heating (e.g., those encountered during decay heating), fractures and pores develop via microscale organic matter decomposition at the organic-mineral interface. In other words, the pores developed here are a result of phase and molecular transformations of the organic solids, rather than thermomechanical coupling. Importantly, the morphologies observed here provide new insight into the connectivity and fluid transmissibility of thermogenic flow paths that potentially undermine waste storage security.

### In Situ Wetting Characterization

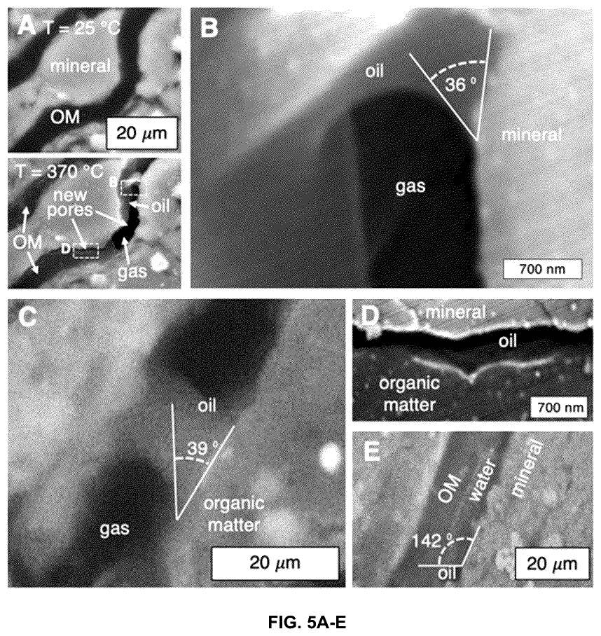

Surface wetting characteristics of thermogenic pores and fractures determine the advection of leaked radionuclides in the aqueous phase. Here, we provide the first in situ nanoscale resolution of dynamic fluid-solid interactions in a porous material (FIG. 5). Specifically, hydrocarbon liquids and gases generated during organic solids thermolysis (heating from 25 to 370° C.) are imaged in a shale sample (FIG. 5A). Fluid distributions are characterized in situ to elucidate their pore-occupancy tendencies (i.e., wettability) and their influence on water transport (FIG. 5B to E).

Operando contact angle measurements at 370° C. show that both the mineral (FIG. 4B) and organic (FIG. 5C) surfaces of the thermogenic flow paths are oil-wetting in the presence of gas. Recall that for heating rates representative of decay heat, hydrocarbon liquids are generated (FIG. 3E) rather than gases (FIG. 3D). It is therefore possible that, during organics thermolysis, hydrocarbon liquids (i.e., oils) imbibe spontaneously into and saturate the newly generated flow paths (FIG. 5D). Importantly, we note that water is non-wetting here (FIG. 5E), and subsequent convection of radionuclide-bearing water through pores and fractures is impeded by the wetting oil phase. In other words, the thermogenic pores and fractures are self-sealed by the wetting hydrocarbon liquids. Together, the wetting characteristics of the mineral and organic surfaces constrain a set of heating rates (i.e., waste density) that enable fractures to self-seal and provides an additional mechanism to contain possible leaked radionuclides.

The operando SEM imaging platform developed here provides first-of-its-kind spatio-temporal-chemical resolution of dynamic fluid-solid interactions in porous materials that underlie a breadth of natural and engineered questions, including the longstanding uncertainties surrounding thermogenic pore and fracture development at organic-mineral interfaces in shale. Powerfully, in situ, visualizations of fluid and flow path evolution at ˜2.5 nm/pixel and ˜10 fps achieved here enable reasonable quantification of reaction rates when compared to bulk characterization. Microscale heterogeneities are captured for the first time, and operando fluid distributions in the generated flow paths provide insight into the self-sealing capacity of argillaceous materials that ensure the long-term storage security of radioactive wastes.

The claims are not intended to include, and should not be interpreted to include, means-plus- or step-plus-function limitations unless such a limitation is explicitly recited in a given claim using the phrase(s) “means for” or “step for,” respectively.

In view of the described processes and compositions, hereinbelow are described certain more particularly described aspects of the inventions. These particularly recited aspects should not, however, be interpreted to have any limiting effect on any different claims containing different or more general teachings described herein or that the “particular” aspects are somehow limited in some way other than the inherent meanings of the language and formulas literally used therein.

### Exemplary Aspects

Example 1. An operando scanning electron microscopy platform comprising: a first cell comprising: (a) a sample well configured to receive a solid sample having at least one dimension up to about 20 mm; and (b) one or more electron beam transparent coverings positioned above the solid sample; wherein the platform is sealed and configured to withstand a pressure up to about 10 MPa and a temperature up to about 500° C.

Example 2. The operando scanning electron microscopy platform of any examples herein, particularly Example 1, wherein the sample well is further configured to receive and host an amount of a fluid and/or gas, such that solid sample-fluid and/or solid sample/fluid interactions are monitored with a scanning electron microscope.

Example 3. The operando scanning electron microscopy platform of any examples herein, particularly Example 1 or 2, wherein the one or more electron beam transparent coverings comprise one or more one electron beam transparent membranes.

Example 4. The operando scanning electron microscopy platform of any examples herein, particularly Example 3, wherein the one or more electron beam transparent membranes comprise graphene, silicon nitride, or any combination thereof.

Example 5. The operando scanning electron microscopy platform of any examples herein, particularly Examples 1-4, wherein the one or more electron beam transparent coverings are positioned within a support frame.

Example 6. The operando scanning electron microscopy platform of any examples herein, particularly Examples 1-5, wherein the sample well and the one or more electron beam transparent coverings are sealed against each other with a compression cover.

Example 7. The operando scanning electron microscopy platform of any examples herein, particularly Examples 1-6, wherein when the solid sample is positioned in the sample well, a tight contact is formed between the solid sample and the one or more electron beam transparent coverings.

Example 8. The operando scanning electron microscopy platform of any examples herein, particularly Examples 1-7, wherein the sample well comprises a thermostable bed positioned at a bottom of the well and wherein the solid sample is positioned on the thermostable bed.

Example 9. The operando scanning electron microscopy platform of any examples herein, particularly Example 8, wherein a thickness of the thermostable bed is adjustable to ensure tight contact between the solid sample and the one or more electron beam transparent coverings.

Example 10. The operando scanning electron microscopy platform of any examples herein, particularly Examples 1-9, further comprising a second cell having dimensions effective to encompass the first cell, wherein the second cell is at least partially thermally insulating the first cell.

Example 11. The operando scanning electron microscopy platform of any examples herein, particularly Examples 1-10, wherein the first cell further comprises one or more orifices configured to receive one or more temperature measuring devices, an electrical connection, heating/cooling elements, a flow of a gas or a fluid, a tubing, or any combination thereof.

Example 12. The operando scanning electron microscopy platform of any examples herein, particularly Example 11, wherein the one or more orifices are in communication with the sample well.

Example 13. The operando scanning electron microscopy platform of any examples herein, particularly Example 11 or 12, wherein the second cell further comprises one or more orifices configured to receive one or more thermal devices, an electrical connection, a gas or a fluid flow, a tubing, or any combination thereof.

Example 14. The operando scanning electron microscopy platform of any examples herein, particularly Example 13, wherein the one or more orifices of the second cell are in communication with the first cell.

Example 15. The operando scanning electron microscopy platform of any examples herein, particularly Example 13 or 14, wherein the one or more orifices of the second cell are in communication with the one or more orifices of the first cell.

Example 16. The operando scanning electron microscopy platform of any examples herein, particularly Examples 1-15, wherein the platform is in communication with one or more heating devices.

Example 17. The operando scanning electron microscopy platform of any examples herein, particularly Example 16, wherein the one or more heating devices are embedded within the platform.

Example 18. The operando scanning electron microscopy platform of any examples herein, particularly Examples 1-17, wherein the platform is in communication with one or more pressure relief valves.

Example 19. The operando scanning electron microscopy platform of any examples herein, particularly Examples 1-18, wherein the platform is in communication with one or more controllers.

Example 20. The operando scanning electron microscopy platform of any examples herein, particularly Example 19, wherein the communication with the one or more controllers is wireless.

Example 21. The operando scanning electron microscopy platform of any examples herein, particularly Example 19 or 20, wherein the one or more controllers are Bluetooth operated.

Example 22. The operando scanning electron microscopy platform of any examples herein, particularly Examples 10-21, wherein the second cell comprises a bottom portion and a top portion, wherein the bottom portion and the top portion are reversibly sealable with each other.

Example 23. The operando scanning electron microscopy platform of any examples herein, particularly Example 22, wherein the bottom portion is configured to house the sample well, has a predetermined wall thickness and comprises a stainless steel, ceramic material, or a composition thereof.

Example 24. The operando scanning electron microscopy platform of any examples herein, particularly Example 22 or 23, wherein the top portion is positioned around a top portion of the first cell such that the least the one or more electron beam transparent coverings are not obscured from an electron beam of a scanning electron microscope.

Example 25. The operando scanning electron microscopy platform of any examples herein, particularly Example 24, wherein the top portion of the second cell thermally insulates the first cell.

Example 26. The operando scanning electron microscopy platform of any examples herein, particularly Example 24 or 25, wherein the top portion of the second cell insulates the first cell from one or more scanning electron microscope detectors.

Example 27. The operando scanning electron microscopy platform any examples herein, particularly Examples 22-26, wherein the top cell comprises a ceramic material.

Example 28. The operando scanning electron microscopy platform of any examples herein, particularly Examples 22-27, wherein the one or more orifices of the second cell are positioned at the top portion, bottom portion, or both.

Example 29. The operando scanning electron microscopy platform of any examples herein, particularly Examples 10-28, wherein the platform comprises a spacing between the first cell and the second cell.

Example 30. The operando scanning electron microscopy platform of any examples herein, particularly Example 29, wherein the spacing comprises an insulating material.

Example 31. The operando scanning electron microscopy platform any examples herein, particularly Examples 19-30, wherein the one or more controllers are configured to heat the sample well to a predetermined temperature at a predetermined rate.

Example 32. The operando scanning electron microscopy platform of any examples herein, particularly Examples 1-31, wherein the platform is configured to operate as a flow-cell.

Example 33. The operando scanning electron microscopy platform of any examples herein, particularly Examples 1-32, wherein the platform is configured to allow the sample visualization with a spatio-temporal-chemical resolution of about 1 nm/pixel to about 50 nm/pixel and up to about 10 fps.

Example 34. The operando scanning electron microscopy platform of any examples herein, particularly Examples 1-33, wherein the platform is adapted for an energy-dispersive X-ray spectroscopy (EDS) elemental mapping.

Example 35. A method comprises: positioning the operando scanning electron microscopy platform of any examples herein, particularly Examples 1-34 comprising a solid sample having at least one dimension up to about 20 mm in an electron microscope chamber; optionally heating and/or pressuring the sample to a temperature up to about 500° C. and/or pressure of 10 MPa; and imaging the solid sample.

Example 36. The method of any examples herein, particularly Example 35, wherein the imaging is continuous.

Example 37. The method of any examples herein, particularly Example 35 or 36, wherein the heating is performed according to a non-isothermal ramp-up stage.

Example 38. The method of any examples herein, particularly Examples 35-37, wherein the method comprises measurement of thermo-chemo-mechanical phenomena of the solid sample.

Example 39. The method of any examples herein, particularly Examples 35-38, wherein the method comprises measurement of wettability of the solid sample.

Example 40. The method of any examples herein, particularly Examples 35-39, wherein the solid sample is a portion of a porous shale structure, natural or engineered porous material, an electrode, a solid catalyst, a plurality of particles, or any combination thereof.

Example 41. The method of any examples herein, particularly Examples 35-40, wherein the sample visualization has a spatio-temporal-chemical resolution of about 1 nm/pixel to about 50 nm/pixel and up to about 10 fps.

Example 42. The method of any examples herein, particularly Examples 35-41, wherein the method further comprise an energy-dispersive X-ray spectroscopy (EDS) elemental mapping of the sample.

Example 43. An electron microscope comprising a chamber configured to receive the operando scanning electron microscopy platform of any examples herein, particularly Examples 1-34.

What is claimed is:

1. An operando scanning electron microscopy platform comprising:
a first cell comprising:
a) a sample well configured to receive a solid sample; and
b) one or more electron beam transparent coverings positioned above the solid sample;
wherein the platform is sealed and configured to withstand a pressure up to about 10 MPa and a temperature up to about 1,000° C.

2. The operando scanning electron microscopy platform of claim 1, wherein the sample well is further configured to receive and host an amount of a fluid and/or gas, such that solid sample-fluid and/or solid sample/fluid interactions are monitored with a scanning electron microscope.

3. The operando scanning electron microscopy platform of claim 1, wherein the one or more electron beam transparent coverings comprise one or more one electron beam transparent membranes.

4. The operando scanning electron microscopy platform of claim 3, wherein the one or more electron beam transparent membranes comprise graphene, silicon nitride, or any combination thereof.

5. The operando scanning electron microscopy platform of claim 1, wherein the one or more electron beam transparent coverings are positioned within a support frame.

6. The operando scanning electron microscopy platform of claim 1, wherein the sample well and the one or more electron beam transparent coverings are sealed against each other with a compression cover.

7. The operando scanning electron microscopy platform of claim 1, wherein when the solid sample is positioned in the sample well, a tight contact is formed between the solid sample and the one or more electron beam transparent coverings.

8. The operando scanning electron microscopy platform of claim 1, wherein the sample well comprises a ttemperature controlled-bed positioned at a bottom of the well and wherein the solid sample is positioned on the thermostable bed.

9. The operando scanning electron microscopy platform of claim 8, wherein a thickness of the thermostable bed is adjustable to ensure tight contact between the solid sample and the one or more electron beam transparent coverings.

10. The operando scanning electron microscopy platform of claim 1, further comprising a second cell having dimensions effective to encompass the first cell, wherein the second cell is at least partially thermally insulating the first cell.

11. The operando scanning electron microscopy platform of claim 1, wherein the first cell further comprises one or more orifices configured to receive one or more temperature measuring devices, an electrical connection,
heating/cooling elements, a flow of a gas or a fluid, a tubing, or any combination thereof.

12. The operando scanning electron microscopy platform of claim 11, wherein the one or more orifices are in communication with the sample well.

13. The operando scanning electron microscopy platform of claim 12, wherein the one or more orifices of the second cell are in communication with the first cell or wherein the one or more orifices of the second cell are in communication with the one or more orifice of the first cell.

14. The operando scanning electron microscopy platform of claim 1, wherein the platform is in communication with one or more heating devices, optionally wherein the one or more heating devices are embedded within the platform.

15. The operando scanning electron microscopy platform of claim 1, wherein the platform is in communication with one or more pressure relief valves.

16. The operando scanning electron microscopy platform of claim 10, wherein the second cell comprises a bottom portion and a top portion, wherein the bottom portion and the top portion are reversibly sealable with each other.

17. The operando scanning electron microscopy platform of claim 16, wherein the top portion of the second cell thermally insulates the first cell.

18. The operando scanning electron microscopy platform of claim 16, wherein the top cell comprises a thermally insulating material.

19. The operando scanning electron microscopy platform of claim 16, wherein the one or more orifices of the second cell are positioned at the top portion, bottom portion, or both.

20. A method comprising:
positioning the operando scanning electron microscopy platform of claim 1 comprising a solid sample in an electron microscope chamber;
optionally heating and/or pressuring the sample to a temperature up to about 1,000° C. and/or pressure of 10 MPa; and
imaging the solid sample.
